(19) United States
(12) Patent Application Publication
(10) Pub. No.: US 2025/0293656 A1
(43) Pub. Date: Sep. 18, 2025

(54) FILTER CIRCUIT

(71) Applicant: Murata Manufacturing Co., Ltd., Kyoto-fu (JP)

(72) Inventor: Yuki OHMAE, Nagaokakyo-shi (JP)

(73) Assignee: Murata Manufacturing Co., Ltd., Kyoto-fu (JP)

(21) Appl. No.: 19/072,210

(22) Filed: Mar. 6, 2025

(30) Foreign Application Priority Data
Mar. 13, 2024 (JP) 2024-039447

(51) Int. Cl. H03H 7/01

(52) U.S. Cl. CPC H03H 7/0115

(57) ABSTRACT

A filter circuit includes: an input terminal; an output terminal; a signal path; an inductor inserted in the signal path; a first capacitor connected to an input path; a second capacitor connected to an output path; and a third capacitor connected to the first capacitor and the second capacitor and connected to a reference potential. The filter circuit includes: a substrate; an element including an inductor; a first electrode connected to an input side of the element; a second electrode connected to an output side of the element; a third electrode being a floating electrode; and a fourth electrode connected to the reference potential. The first electrode and the third electrode face each other to form the first capacitor. The second electrode and the third electrode face each other to form the second capacitor. The third electrode and the fourth electrode face each other to form the third capacitor.

### CROSS-REFERENCE TO RELATED APPLICATION

This application claims benefit of priority to Japanese Patent Application No. 2024-039447, filed Mar. 13, 2024, the entire content of which is incorporated herein by reference.

### BACKGROUND

### Technical Field

The present disclosure relates to a filter circuit.

### Background Art

Japanese Unexamined Patent Application Publication No. 2006-262349 describes a resonant circuit that attenuates a specific frequency.

### SUMMARY

However, in the resonant device described in Japanese Unexamined Patent Application Publication No. 2006-262349, in order to secure the capacitance of capacitors, it is necessary to increase the size of electrodes.

Accordingly, the present disclosure provides a smaller filter circuit.

A filter circuit according to an aspect of the present disclosure includes an input terminal; an output terminal; a signal path connecting the input terminal and the output terminal; an inductor inserted in series into the signal path; a first capacitor having one electrode connected to an input path connecting the input terminal and the inductor; a second capacitor having one electrode connected to an output path connecting the output terminal and the inductor; and a third capacitor having one electrode connected to the first capacitor and the second capacitor and the other electrode connected to a reference potential. The filter circuit includes a substrate whose thickness is in a first direction; an element provided on a main surface of the substrate and/or in the substrate and including the inductor; a first electrode provided on the main surface of the substrate and/or in the substrate and connected to a terminal of the element on the input terminal side; a second electrode provided on the main surface of the substrate and/or in the substrate and connected to a terminal of the element on the output terminal side; a third electrode that is a floating electrode and that is provided in the substrate; and a fourth electrode provided on a main surface facing the main surface of the substrate in the first direction and/or in the substrate and connected to the reference potential. At least a portion of the first electrode and at least a portion of the third electrode face each other in the first direction. At least a portion of the second electrode and at least a portion of the third electrode face each other in the first direction. At least a portion of the third electrode and at least a portion of the fourth electrode face each other in the first direction. The portion of the first electrode facing the third electrode in the first direction is the electrode of the first capacitor. The portion of the second electrode facing the third electrode in the first direction is the electrode of the second capacitor. The portion of the third electrode facing the first electrode in the first direction is the other electrode of the first capacitor. The portion of the third electrode facing the second electrode in the first direction is the other electrode of the second capacitor. The portion of the third electrode facing the fourth electrode in the first direction is the electrode of the third capacitor. The portion of the fourth electrode facing the third electrode in the first direction is the other electrode of the third capacitor.

According to the present disclosure, a smaller filter circuit can be provided.

### BRIEF DESCRIPTION OF THE DRAWINGS

FIG. 1 is a schematic view showing a main surface of a filter circuit according to a first embodiment;

FIG. 2 is a schematic view showing the inside of the filter circuit according to the first embodiment;

FIG. 3 is a cross-sectional view taken along the line III-III in FIGS. 1 and 2;

FIG. 4 is a circuit diagram showing the filter circuit according to the first embodiment;

FIG. 5 is a circuit diagram showing an equivalent circuit of the filter circuit shown in FIG. 1;

FIG. 6 is a schematic view showing the inside of a filter circuit according to a first modification;

FIG. 7 is a schematic view showing the inside of a filter circuit according to a second modification;

FIG. 8 is a schematic view showing the inside of a filter circuit according to a third modification;

FIG. 9 is a circuit diagram showing the filter circuit according to the third modification;

FIG. 10 is a schematic view showing the inside of a filter circuit according to a second embodiment;

FIG. 11 is a cross-sectional view taken along the line XI-XI in FIG. 10;

FIG. 12 is a circuit diagram showing the filter circuit according to the second embodiment;

FIG. 13 is a schematic view showing a main surface of a substrate of a filter circuit according to a third embodiment;

FIG. 14 is a schematic view showing the inside of the substrate of the filter circuit according to the third embodiment;

FIG. 15 is a schematic view showing the inside of the substrate of the filter circuit according to the third embodiment;

FIG. 16 is a schematic view showing the inside of the substrate of the filter circuit according to the third embodiment;

FIG. 17 is a cross-sectional view taken along the line XVII-XVII in FIGS. 13 to 16;

FIG. 18 is a circuit diagram showing the filter circuit according to the third embodiment;

FIG. 19 is a schematic view showing a main surface of a substrate of a filter circuit according to a fourth modification;

FIG. 20 is a schematic view showing a main surface of a substrate of a filter circuit according to a fifth modification;

FIG. 21 is a circuit diagram showing a filter circuit according to a sixth modification;

FIG. 22 is a schematic view showing a main surface of a substrate of a filter circuit according to a seventh modification;

FIG. 23 is a circuit diagram of the filter circuit according to the seventh modification;

FIG. 24 is a schematic view showing a main surface of a substrate of a filter circuit according to a fourth embodiment;

FIG. 25 is a schematic view showing the inside of the substrate of the filter circuit according to the fourth embodiment; and

FIG. 26 is a circuit diagram of the filter circuit according to the fourth embodiment.

### DETAILED DESCRIPTION

Embodiments and modifications of the present disclosure will be described below. Note that the present disclosure is not limited by these embodiments and modifications. Each of the respective embodiments and modifications is an example, and it is needless to say that the configurations described in different embodiments and modifications can be partially replaced or combined. Further, in each of the embodiment and modification, descriptions for the same configurations, effects and actions as in the first embodiment are omitted.

### First Embodiment

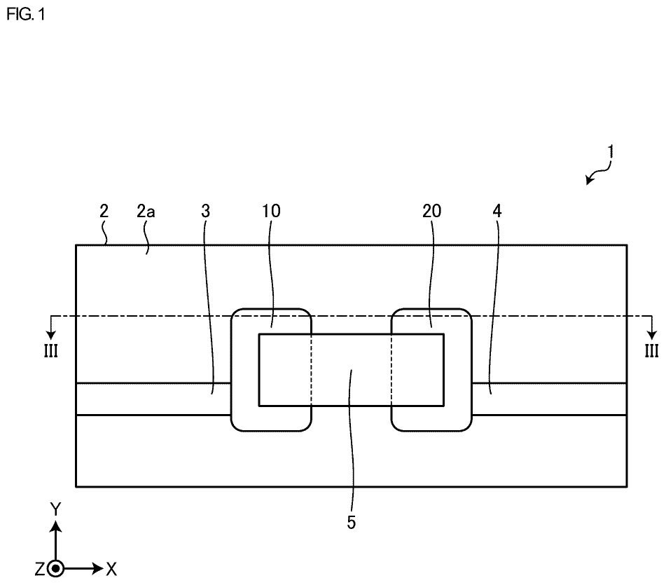

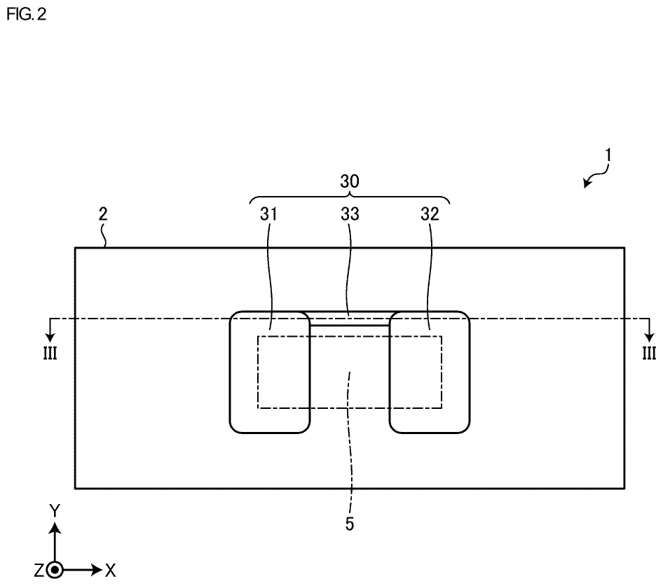

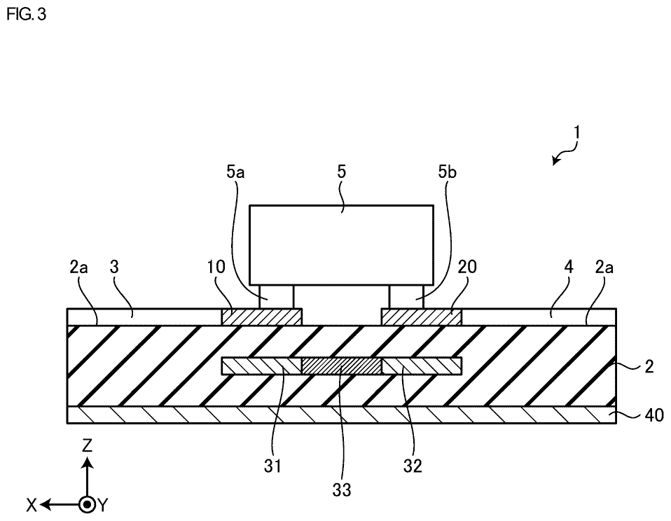

FIG. 1 is a schematic view showing a main surface of a filter circuit according to a first embodiment. FIG. 2 is a schematic view showing the inside of the filter circuit according to the first embodiment. FIG. 3 is a cross-sectional view taken along the line III-III in FIGS. 1 and 2. As shown in FIGS. 1 to 3, a filter circuit 1 according to the first embodiment is a circuit formed in or on a substrate 2. As shown in FIGS. 1 to 3, the filter circuit 1 according to the first embodiment includes the substrate 2, main lines 3 and 4, an element 5, a first electrode 10, a second electrode 20, a third electrode 30, and a fourth electrode 40.

Examples of the substrate 2 include a ceramic laminated substrate, a resin multilayer substrate, and a film substrate; in which examples of the ceramic laminated substrate include a low temperature co-fired ceramics (LTCC) substrate. The base material of the substrate 2 is a dielectric. The substrate 2 has a main surface 2a. In the following description, the thickness direction of the substrate 2 is defined as a Z direction, the direction perpendicular to the Z direction is defined as an X direction, and the directions perpendicular to the Z direction and the X direction are defined as a Y direction. Here, the Z direction is an example of a first direction.

The main lines 3 and 4 are signal paths of the filter circuit 1. The main line 3 is a portion of a line connecting an input terminal IN of the filter circuit 1 and the first electrode 10 of the filter circuit 1. In the example shown in FIG. 1, the main line 3 is connected to the input terminal IN (not shown) on one side in the X direction and to the first electrode 10 on the other side in the X direction. The main line 4 is a portion of a line connecting an output terminal OUT of the filter circuit 1 and the second electrode 20 of the filter circuit 1. In the example shown in FIG. 1, the main line 4 is connected to the first electrode 10 on one side in the X direction and to the output terminal OUT (not shown) on the other side in the X direction.

The element 5 is a surface mount device (SMD) including an inductor L0, which is to be described later. The element 5 is provided on the main surface 2a of the substrate 2. One terminal 5a of the element 5 is connected to the input terminal IN via the first electrode 10. The other terminal 5b of the element 5 is connected to the output terminal OUT via the second electrode 20. The terminals 5a and 5b are conductive bonding materials such as a solder paste containing a low-melting metal. Here, the low-melting metal is called solder and is, for example, a tin alloy.

The first electrode 10 is an electrode connected to the terminal 5a of the element 5 on the input terminal IN side. In the first embodiment, the first electrode 10 is provided on the main surface 2a of the substrate 2. The first electrode 10 is connected to the main line 3. Here, the first electrode 10 is an electrode whose minimum length when viewed in plan in the Z direction is larger than the width of the main line 3. The width of the main line 3 means the average of the lengths of the main line 3 in the direction perpendicular to the extension direction. In the example of FIG. 1, the width of the main line 3 means the length of the main line 3 in the Y direction. The minimum length of the first electrode 10 means the minimum distance between two different points on the edge of the first electrode 10. In the example of FIG. 1, the minimum length of the first electrode 10 means the length of the first electrode 10 in the X direction. In the example of FIG. 1, the first electrode 10 is connected to the main line 3 on one side in the X direction, but this is only an example, and the connection of the first electrode 10 is not limited to such an example as long as the first electrode 10 can be connected to the main line 3. The shape of the first electrode 10 is a rectangle with rounded corners; however, the shape of the first electrode 10 is not limited to a rectangle with rounded corners, but can be other shapes such as a circle.

The second electrode 20 is an electrode connected to the terminal 5b of the element 5 on the output terminal OUT side. In the first embodiment, the second electrode 20 is provided on the main surface 2a of the substrate 2. Therefore, the second electrode 20 is connected to the main line 4. Here, the second electrode 20 is an electrode whose minimum length when viewed in plan in the Z direction is larger than the width of the main line 4. The width of the main line 4 means the average of the lengths of the main line 4 in the direction perpendicular to the extension direction. In the example of FIG. 1, the width of the main line 4 means the length of the main line 4 in the Y direction. The minimum length of the second electrode 20 means the minimum distance between two different points on the edge of the second electrode 20. In the example of FIG. 1, the minimum length of the second electrode 20 means the length of the second electrode 20 in the X direction. In the example of FIG. 1, the second electrode 20 is connected to the main line 4 on the other side in the X direction, but this is only an example, and the connection of the second electrode 20 is not limited to such an example as long as the second electrode 20 can be connected to the main line 4. The shape of the second electrode 20 is a rectangle with rounded corners; however, the shape of the second electrode 20 is not limited to a rectangle with rounded corners, but can be other shapes such as a circle.

The third electrode 30 is a floating electrode. In the present disclosure, a floating electrode refers to an electrode that is not directly connected to a line where a radio frequency signal is transmitted, i.e., an RF (radio frequency) line, or a reference potential (ground GND). In the first embodiment, the third electrode 30 is provided in the substrate 2 so as to be separated from the first electrode 10 and the second electrode 20 in the Z direction. In the first embodiment, the third electrode 30 includes electrode pads 31 and 32 and a connecting portion 33. In the example of FIG. 2, the electrode pads 31 and 32 and the connecting portion 33 are provided on the same plane. In the first embodiment, the electrode pad 32 has the same shape as the second electrode 20. The connecting portion 33 is a portion electrically connecting the electrode pad 31 and the electrode pad 32. In the first embodiment, the connecting portion 33 is provided extending in the Y direction so as not to overlap the element 5 when viewed in plan in the Z direction. With such a configuration, the interaction between the connecting portion 33 and the element 5 can be suppressed. In the example of FIG. 2, the width of the connecting portion 33 is smaller than the minimum length of the electrode pads 31 and 32 when viewed in plan in the Z direction. The width of the connecting portion 33 means the average of the lengths of the connecting portion 33 in the direction perpendicular to the extension direction. In the example of FIG. 2, the width of the connecting portion 33 means the length of the connecting portion 33 in the Y direction. The minimum length of the electrode pads 31 and 32 means the minimum distance between two different points on the edges of the electrode pads 31 and 32. In the example of FIG. 2, the minimum length of the electrode pads 31 and 32 means the length of the electrode pads 31 and 32 in the X direction.

The fourth electrode 40 is an electrode connected to the reference potential, i.e., the ground GND, which is to be described later. In the example of FIG. 3, the fourth electrode 40 is provided on the other main surface of the substrate 2, that is, a main surface opposite to the main surface 2a (i.e., a main surface facing the main surface 2a in the Z direction). In the first embodiment, the fourth electrode 40 is provided so as to be separated from the third electrode 30 in the Z direction.

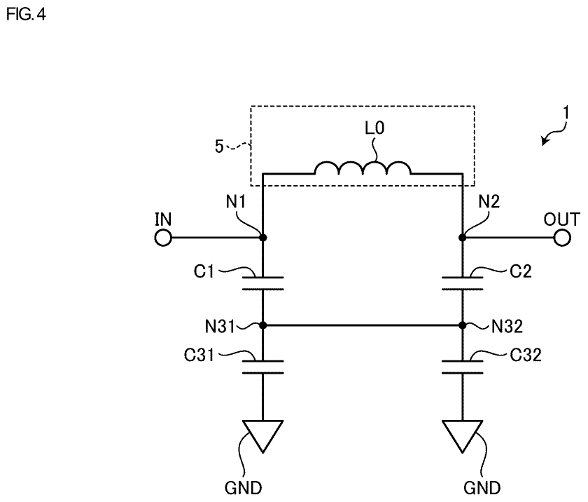

FIG. 4 is a circuit diagram showing the filter circuit according to the first embodiment. As shown in FIG. 4, the filter circuit 1 according to the first embodiment includes the input terminal IN, the output terminal OUT, the inductor L0, a first capacitor C1, a second capacitor C2, and third capacitors C31 and C32. The inductor L0 is inserted in series into a signal path connecting the input terminal IN and the output terminal OUT. One electrode of the first capacitor C1 is connected to a node N1 on an input path connecting the input terminal IN and the inductor L0. The other electrode of the first capacitor C1 is connected to one electrode of the third capacitor C31. One electrode of the second capacitor C2 is connected to a node N2 on an input path connecting the output terminal OUT and the inductor L0. The other electrode of the second capacitor C2 is connected to one electrode of the third capacitor C32. Here, a node N31 on a path connecting the first capacitor C1 and the third capacitor C31 and a node N32 on a path connecting the second capacitor C2 and the third capacitor C32 are electrically connected. Therefore, the first capacitor C1 and the second capacitor C2 are connected in series, and the inductor L0 is connected in parallel with the first capacitor C1 and the second capacitor C2. With such a configuration, by properly adjusting the electrostatic capacities of the first capacitor C1, the second capacitor C2 and a third capacitor C3 and the inductance of the inductor L0, the signal can be attenuated at a desired attenuation pole by the parallel-resonant circuit.

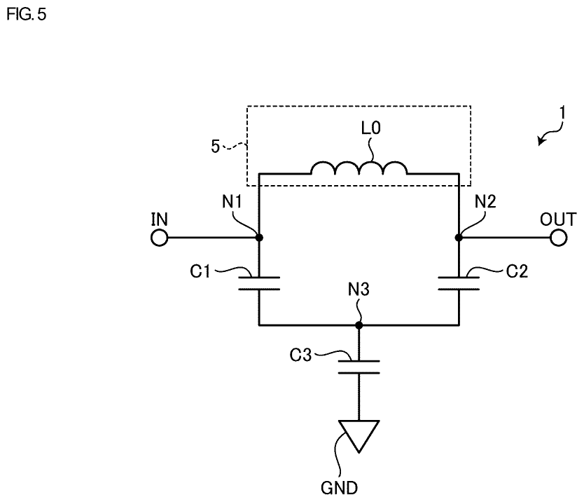

FIG. 5 is a circuit diagram showing an equivalent circuit of the filter circuit shown in FIG. 1. In the first embodiment, since the node N31 and the node N32 are electrically connected, the filter circuit according to the first embodiment is equivalent to the circuit shown in FIG. 5. In the first embodiment, the third capacitor C3 is a capacitor having the combined capacitance of the third capacitors C31 and C32. One electrode of the third capacitor C3 is connected to a node N3 that is connected to the other electrode of the first capacitor C1 and the other electrode of the second capacitor C2. The other electrode of the third capacitor C3 is connected to the reference potential (the ground GND).

Here, the electrostatic capacity of the first capacitor C1 and the electrostatic capacity of the second capacitor C2 are preferably 0.03 pF or larger. With such a configuration, since the electrostatic capacities of the first capacitor C1 and the second capacitor C2 contribute to the resonance characteristics, the signal can be attenuated at a desired attenuation pole.

In the first embodiment, the third electrode 30 has a portion facing at least a portion of the first electrode 10 in the Z direction. In the present disclosure, the fact that the electrodes face each other in the Z direction means that there is no conductor between the two electrodes in the Z direction. In the example of FIG. 2, the electrode pad 31 of the third electrode 30 faces the entire first electrode 10 in the Z direction. As a result, the first capacitor C1 is formed by the first electrode 10 and the electrode pad 31. That is, the first electrode 10 corresponds to the node N1, and at least a portion of the first electrode 10 corresponds to one electrode of the first capacitor C1. Further, at least a portion of the third electrode 30 corresponds to the other electrode of the first capacitor C1. In the example of FIG. 2, the first electrode 10 corresponds to one electrode of the first capacitor C1, and the electrode pad 31 of the third electrode 30 corresponds to the other electrode of the first capacitor C1.

In the first embodiment, the third electrode 30 has a portion facing at least a portion of the second electrode 20 in the Z direction. In the example of FIG. 2, the electrode pad 32 of the third electrode 30 faces the entire second electrode 20 in the Z direction. As a result, the first capacitor C1 is formed by the portions of the third electrode 30 and second electrode 20 facing each other. In the example of FIG. 2, the second capacitor C2 is formed by the second electrode 20 and the electrode pad 32. That is, the second electrode 20 corresponds to the node N2, and at least a portion of the second electrode 20 corresponds to one electrode of the second capacitor C2. Further, at least a portion of the third electrode 30 corresponds to the other electrode of the second capacitor C2. In the example of FIG. 2, the second electrode 20 corresponds to one electrode of the second capacitor C2, and the electrode pad 32 of the third electrode 30 corresponds to the other electrode of the second capacitor C2.

In the first embodiment, the third electrode 30 has a portion facing at least a portion of the fourth electrode 40 in the Z direction. In the example of FIG. 2, the electrode pad 31 and the electrode pad 32 face at least a portion of the fourth electrode 40. As a result, the third capacitor C31 is formed by the electrode pad 31 and the fourth electrode 40, and the third capacitor C32 is formed by the electrode pad 32 and the fourth electrode 40. That is, at least a portion of the third electrode 30 corresponds to one electrode of the third capacitors C31 and C32, and at least a portion of the fourth electrode 40 corresponds to the other electrode of the third capacitors C31 and C32. In the example of FIG. 2, the electrode pad 31 of the third electrode 30 corresponds to one electrode of the third capacitor C31, and the electrode pad 32 of the third electrode 30 corresponds to one electrode of the third capacitor C32.

As described above, the filter circuit 1 according to the first embodiment includes: an input terminal IN; an output terminal OUT; a signal path connecting the input terminal IN and the output terminal OUT; an inductor L0 inserted in series into the signal path; a first capacitor C1 having one electrode connected to an input path connecting the input terminal IN and the inductor L0; a second capacitor C2 having one electrode connected to an output path connecting the output terminal OUT and the inductor L0, and a third capacitor C3 having one electrode connected to the first capacitor C1 and the second capacitor C2 and the other electrode connected to the reference potential (the ground GND). The filter circuit 1 includes: a substrate 2 whose thickness is in a first direction (Z direction); an element 5 provided on a main surface 2a of the substrate 2 and/or in the substrate 2 and including the inductor L0; a first electrode 10 provided on the main surface 2a of the substrate 2 and/or in the surface 2a and connected to a terminal of the element 5 on the input terminal IN side; a second electrode 20 provided on the main surface 2a of the substrate 2 and/or in the substrate 2 and connected to a terminal of the element 5 on the output terminal OUT side; a third electrode 30 that is a floating electrode and that is provided in the substrate 2; and a fourth electrode 40 provided on a main surface of the substrate 2 facing the main surface 2a and/or in the substrate 2 and connected to the reference potential. At least a portion of the first electrode 10 and at least a portion of the third electrode 30 face each other in the first direction. At least a portion of the second electrode 20 and at least a portion of the third electrode 30 face each other in the first direction. At least a portion of the third electrode 30 and at least a portion of the fourth electrode 40 face each other in the first direction. The portion of the first electrode 10 facing the third electrode 30 in the first direction is one electrode of the first capacitor C1. The portion of the second electrode 20 facing the third electrode 30 in the first direction is one electrode of the second capacitor C2. The portion of the third electrode 30 facing the first electrode 10 in the first direction (the electrode pad 31) is the other electrode of the first capacitor C1. The portion of the third electrode 30 facing the second electrode 20 in the first direction (the electrode pad 32) is the other electrode of the second capacitor C2. The portion of the third electrode 30 facing the fourth electrode 40 in the first direction is one electrode of the third capacitor C3. The portion of the fourth electrode 40 facing the third electrode 30 in the first direction is the other electrode of the third capacitor C3.

With such a configuration, since the area of the electrodes can be reduced without reducing the electric capacitance as compared with a case where the capacitors are formed by forming the electrodes on both main surfaces of the substrate 2, a smaller filter circuit 1 can be provided.

As a desirable aspect, the electrostatic capacity of the first capacitor C1 is 0.03 pF or larger, and the electrostatic capacity of the second capacitor C2 is 0.03 pF or larger. With such a configuration, since the electrostatic capacities of the first capacitor C1 and the second capacitor C2 contribute to the resonance characteristics, the signal can be attenuated at a desired attenuation pole.

As a desirable aspect, the third electrode 30 has a connecting portion 33 that connects the portion (the electrode pad 31) facing at least a portion of the first electrode 10 in the first direction and the portion (the electrode pad 32) facing at least a portion of the second electrode 20 in the first direction. With such a configuration, since the electrostatic capacities of the first capacitor C1 and the second capacitor C2 contribute to the resonance characteristics, the signal can be attenuated at a desired attenuation pole.

As a desirable aspect, the connecting portion 33 does not overlap with the element 5 when viewed in plan in the first direction. With such a configuration, the occurrence of the parasitic capacitance between the connecting portion 33 and the element 5 can be suppressed.

As a desirable aspect, the element 5 is a surface mount device. With such a configuration, since the inductance of the inductor L0 can be increased and the capacitances of the first capacitor C1 and the second capacitor C2 can be reduced, the area of the electrodes can be further reduced, so that a smaller filter circuit 1 can be provided.

### First Modification

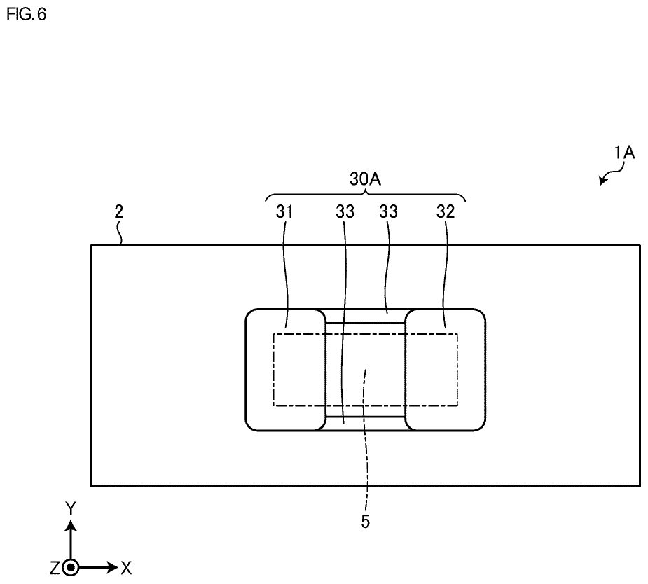

FIG. 6 is a schematic view showing the inside of a filter circuit according to a first modification. As shown in FIG. 6, in a filter circuit 1A according to the first modification, a third electrode 30A has a plurality of connecting portions 33. In the example of FIG. 6, the third electrode 30A has two connecting portions 33. One connecting portion 33 is provided on one side of the element 5 in the Y direction. The other connecting portion 33 is provided on the other side of the element 5 in the Y direction. With such a structure, the parasitic inductance generated at the wiring line (the connecting portion 33) connecting the electrode pad 31 and the electrode pad 32 can be reduced, and the influence of the parasitic inductance generated at the portion where the first capacitor C1 and the second capacitor C2 are connected on the filter characteristics can be reduced.

### Second Modification

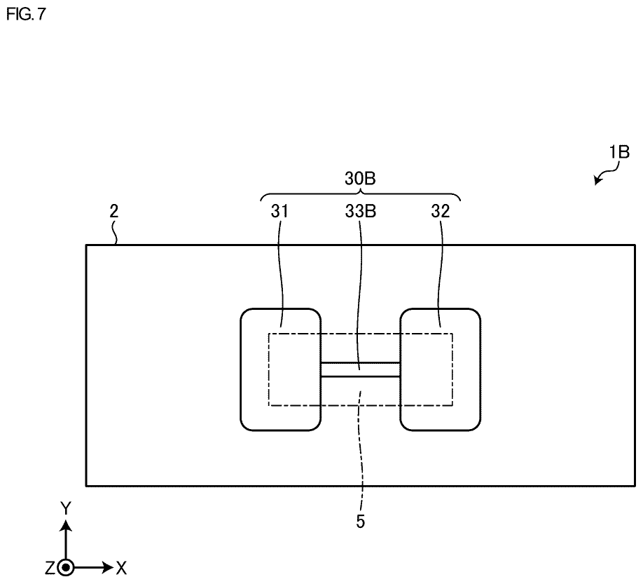

FIG. 7 is a schematic view showing the inside of a filter circuit according to a second modification. As shown in FIG. 7, in a filter circuit 1B according to the second modification, a connecting portion 33B of a third electrode 30B is provided at a position overlapping with the element 5 when viewed in plan in the Z direction. With such a structure, since the element 5 and the entire connecting portion 33B overlap with each other, the parasitic capacitance generated between the element 5 and the connecting portion 33B does not change even if the mounting position of the element 5 is slightly shifted in the Y direction, and the filter design can be made while taking into account the parasitic capacitance generated between the element 5 and the connecting portion 33B.

### Third Modification

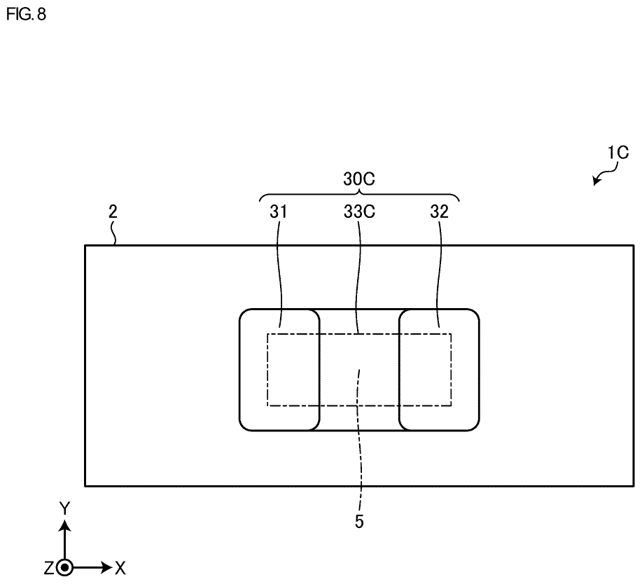

FIG. 8 is a schematic view showing the inside of a filter circuit according to a third modification. As shown in FIG. 8, in a filter circuit 1C according to the third modification, the width of a connecting portion 33C of a third electrode 30C is larger than the widths of the main lines 3 and 4. In the example of FIG. 8, the length of the connecting portion 33C in the Y direction is equal to the widths of the electrode pads 31 and 32, and the edges of the connecting portion 33C in the Y direction overlap with a straight line connecting the edges of the electrode pads 31 and 32 in the Y direction. That is, in the example of FIG. 8, the third electrode 30C is a rectangular electrode.

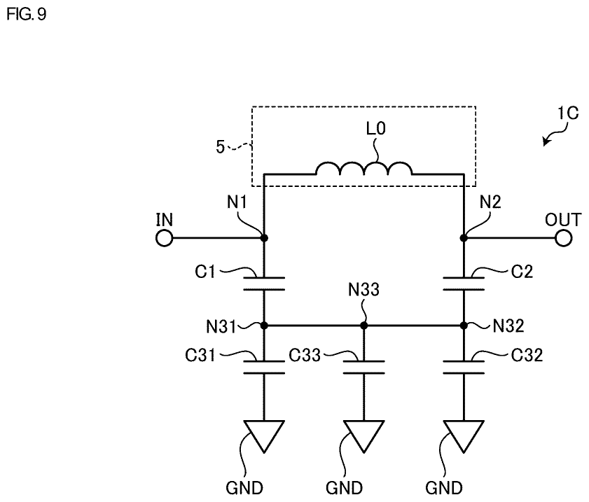

FIG. 9 is a circuit diagram showing the filter circuit according to the third modification. As shown in FIG. 9, the filter circuit 1C according to the third modification further includes a third capacitor C33 formed by the connecting portion 33C and the fourth electrode 40. One end of the third capacitor C33 is connected to a node N33 between the node N31 and the node N32, and the other end of the third capacitor C33 is connected to the ground GND. The filter circuit according to the third modification is also equivalent to the circuit shown in FIG. 5. In the third modification, the third capacitor C3 of the circuit shown in FIG. 5 corresponds to a capacitor having the combined capacitance of the third capacitors C31, C32, and C33.

In the third modification, since the width of the connecting portion 33C in the Y direction is large, an electrostatic capacity is generated between the connecting portion 33C and a portion of the fourth electrode 40. As a result, the third capacitor C3 is formed between the connecting portion 33C and a portion of the fourth electrode 40. That is, the connecting portion 33C corresponds to one electrode of the third capacitor C33 and the node N33, and the portion of the fourth electrode 40 corresponds to the other electrode of the third capacitor C33.

### Second Embodiment

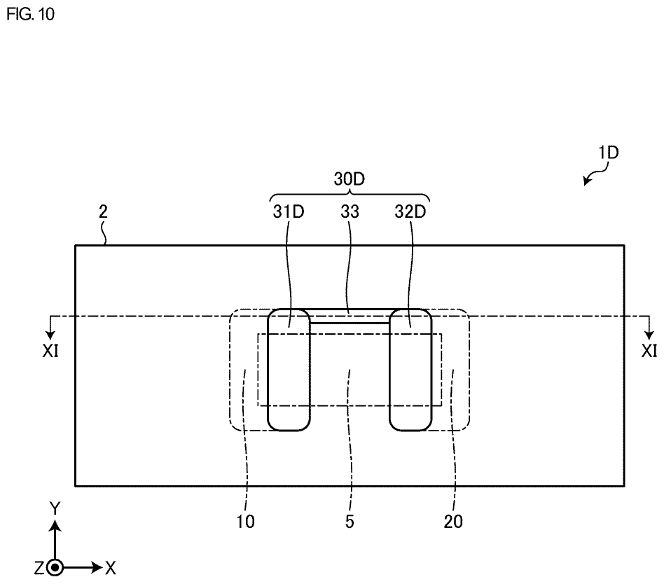

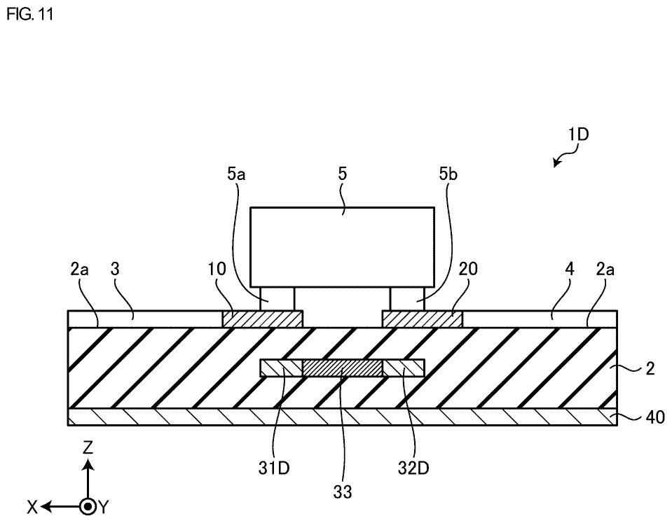

FIG. 10 is a schematic view showing the inside of a filter circuit according to a second embodiment. FIG. 11 is a cross-sectional view taken along the line XI-XI in FIG. 10. As shown in FIGS. 10 and 11, a filter circuit 1D according to the second embodiment differs from the first embodiment in that a third electrode 30D faces only a portion of the first electrode 10 and a portion of the second electrode 20.

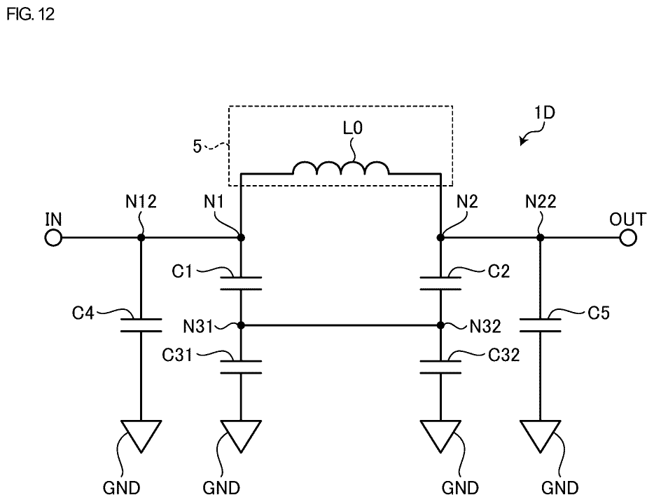

FIG. 12 is a circuit diagram showing the filter circuit according to the second embodiment. The filter circuit 1D according to the second embodiment further includes a fourth capacitor C4 and a fifth capacitor C5. One end of the fourth capacitor C4 is connected to a node N12 between the node N1 and the input terminal IN, and the other end of the fourth capacitor C4 is connected to the ground GND. One end of the fifth capacitor C5 is connected to a node N22 between the node N2 and the output terminal OUT, and the other end of the fifth capacitor C5 is connected to the ground GND.

In the second embodiment, an electrode pad 31D of the third electrode 30D faces a portion of the first electrode 10 in the Z direction. That is, the first electrode 10 has a portion facing the electrode pad 31 of the third electrode 30D and a portion not facing the electrode pad 31 of the third electrode 30D. In the example of FIG. 11, the portion of the first electrode 10 not facing the electrode pad 31 of the third electrode 30D faces a portion of the fourth electrode 40. As a result, the first capacitor C1 is formed by the portion of the first electrode 10 facing the electrode pad 31 and the electrode pad 31 of the third electrode 30D. Further, an electrostatic capacity is generated between the portion of the first electrode 10 not facing the electrode pad 31 of the third electrode 30D and the portion of the fourth electrode 40, so that the fourth capacitor C4 is formed. That is, the portion of the first electrode 10 not facing the electrode pad 31 of the third electrode 30D corresponds to one electrode of the fourth capacitor C4 and the node N12, and the portion of the fourth electrode 40 corresponds to the other electrode of the fourth capacitor C4.

In the second embodiment, an electrode pad 32D of the third electrode 30D faces a portion of the second electrode 20 in the Z direction. That is, the second electrode 20 has a portion facing the electrode pad 32 and a portion not facing the electrode pad 32 of the third electrode 30D. In the example of FIG. 11, the portion of the second electrode 20 not facing the electrode pad 32 of the third electrode 30D faces a portion of the fourth electrode 40. As a result, the second capacitor C2 is formed by the portion of the second electrode 20 facing the electrode pad 32 and the electrode pad 32. Further, an electrostatic capacity is generated between the portion of the second electrode 20 not facing the electrode pad 32 of the third electrode 30D and the portion of the fourth electrode 40, so that the fifth capacitor C5 is formed. That is, the portion of the second electrode 20 not facing the electrode pad 32 of the third electrode 30D corresponds to one electrode of the fifth capacitor C5 and the node N22, and the portion of the fourth electrode 40 corresponds to the other electrode of the fifth capacitor C5.

As described above, in the filter circuit 1D according to the second embodiment, at least a portion of at least one of the first electrode 10 and the second electrode 20 and at least a portion of the fourth electrode 40 face each other in the first direction. With such a configuration, since the attenuation pole of the filter circuit 1D is broadened by the fourth capacitor C4 and the fifth capacitor C5, the attenuation band can be widened.

As described above, the filter circuit 1D according to the second embodiment further includes a capacitor (the fourth capacitor C4) having one electrode connected to the input path and the other electrode connected to the reference potential. At least a portion of the first electrode 10 and at least a portion of the fourth electrode 40 face each other in the first direction. With such a configuration, since the attenuation pole of the filter circuit 1D is broadened by the capacitor (the fourth capacitor C4), the attenuation band can be widened.

Further, the filter circuit 1D according to the second embodiment further includes a capacitor (the fifth capacitor C5) having one electrode connected to the output path and the other electrode connected to the reference potential. At least a portion of the second electrode 20 and at least a portion of the fourth electrode 40 face each other in the first direction. With such a configuration, since the attenuation pole of the filter circuit 1D is broadened by the capacitor (the fifth capacitor C5), the attenuation band can be widened.

### Third Embodiment

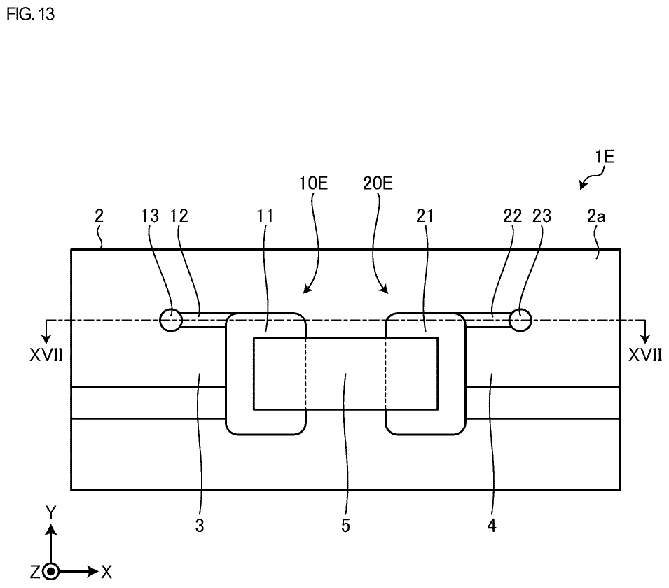

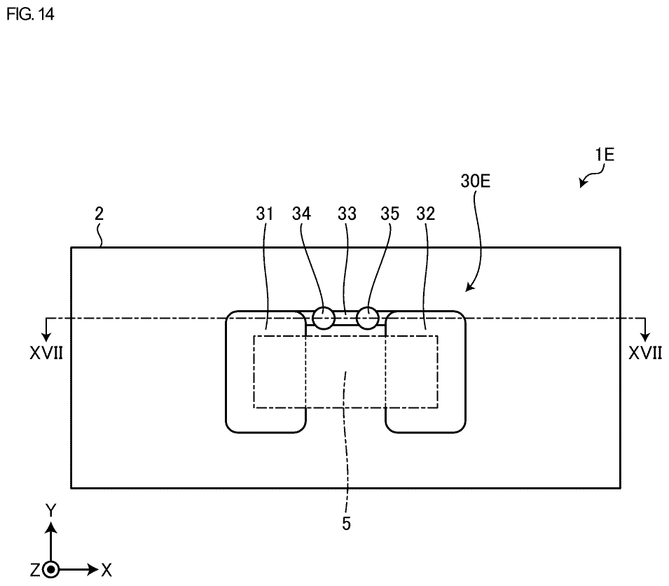

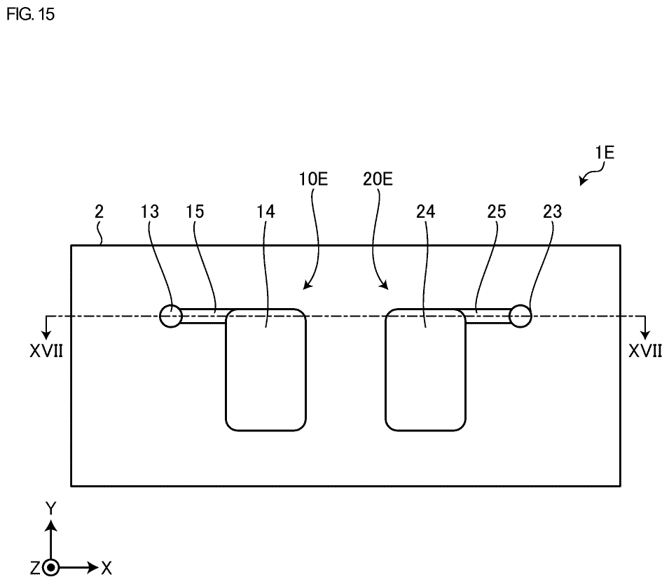

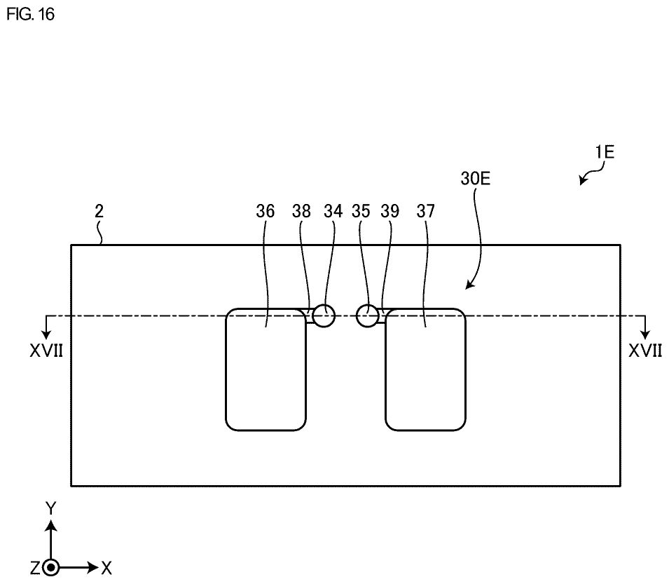

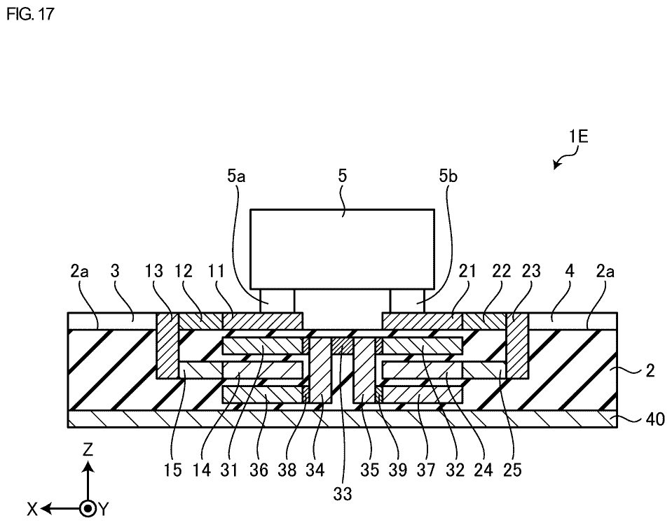

FIG. 13 is a schematic view showing a main surface of a substrate of a filter circuit according to a third embodiment. FIG. 14 is a schematic view showing the inside of the substrate of the filter circuit according to the third embodiment. FIG. 15 is a schematic view showing the inside of the substrate of the filter circuit according to the third embodiment. FIG. 16 is a schematic view showing the inside of the substrate of the filter circuit according to the third embodiment. FIG. 17 is a cross-sectional view taken along the line XVII-XVII in FIGS. 13 to 16. As shown in FIGS. 13 to 17, a filter circuit 1E according to the third embodiment differs from the first embodiment in that a first electrode 10E, a second electrode 20E, and a third electrode 30E are alternately overlapped with each other.

In the third embodiment, the first electrode 10D has portions that overlap with each other when viewed in the Z direction. The first electrode 10D includes electrode pads 11 and 14, lines 12 and 15, and a via 13. The electrode pad 11 is connected to the terminal 5a of the element 5 on the input terminal IN side and is provided on the main surface 2a of the substrate 2. In the example of FIG. 13, the electrode pad 11 has the same shape as the first electrode 10 of the first embodiment. The line 12 is connected to the electrode pad 11 and is provided on the main surface 2a of the substrate 2. In the example of FIG. 13, the line 12 extends in the X direction from the electrode pad 11. The via 13 is connected to the line 12 and extends in the Z direction from the main surface 2a of the substrate 2 to the inside of the substrate 2. The line 15 is connected to the via 13 and is provided in the substrate 2. In the example of FIG. 15, the line 15 extends in the X direction from the via 13. The electrode pad 14 is connected to the line 15 and is provided in the substrate 2. In the example of FIG. 15, the electrode pad 14 has the same shape as the first electrode 10 according to the first embodiment and overlaps with the electrode pad 11 when viewed in plan in the Z direction. Thus, the electrode pads 11 and 14 form the portions of the first electrode 10D that overlap with each other when viewed in the Z direction.

In the third embodiment, the second electrode 20D has portions that overlap with each other when viewed in the Z direction. The second electrode 20D includes electrode pads 21 and 24, lines 22 and 25, and a via 23. The electrode pad 21 is connected to the terminal 5b of the element 5 on the output terminal OUT side and is provided on the main surface 2a of the substrate 2. In the example of FIG. 13, the electrode pad 21 has the same shape as the second electrode 20 of the second embodiment. That is, the line 22 is connected to the electrode pad 21 and is provided on the main surface 2a of the substrate 2. In the example of FIG. 13, the line 22 extends in the X direction from the electrode pad 21. The via 23 is connected to the line 22 and extends in the Z direction from the main surface 2a of the substrate 2 to the inside of the substrate 2. The line 25 is connected to the via 23 and is provided in the substrate 2. In the example of FIG. 15, the line 25 extends in the X direction from the via 23. The electrode pad 24 is connected to the line 25 and is provided in the substrate 2. In the example of FIG. 15, the electrode pad 24 has the same shape as the second electrode 20 according to the first embodiment and overlaps with the electrode pad 21 when viewed in plan in the Z direction. Thus, the electrode pads 21 and 24 form the portions of the second electrode 20D that overlap with each other when viewed in the Z direction.

In the third embodiment, the third electrode 30D has portions that overlap with each other when viewed in the Z direction. The third electrode 30D further includes vias 34 and 35, electrode pads 36 and 37, and lines 38 and 39. The vias 34 and 35 are connected to the connecting portion 33 and extend in the substrate 2 in the Z direction. In the example of FIG. 16, the via 34 is provided on the electrode pad 31 side, and the via 35 is provided on the electrode pad 32 side. The lines 38 and 39 are connected to the vias 34 and 35, respectively, and extend in the X direction from the vias 34 and 35. The electrode pads 36 and 37 are connected to the lines 38 and 39, respectively, and are provided in the substrate 2. In the example of FIG. 16, the electrode pads 36 and 37 have the same shape as the electrode pads 31 and 32, and overlap with the electrode pads 31 and 32 when viewed in plan in the Z direction. Thus, the electrode pads 31 and 36 and the electrode pads 32 and 37 are the portions of the third electrode 30D that overlap with each other when viewed in the Z direction.

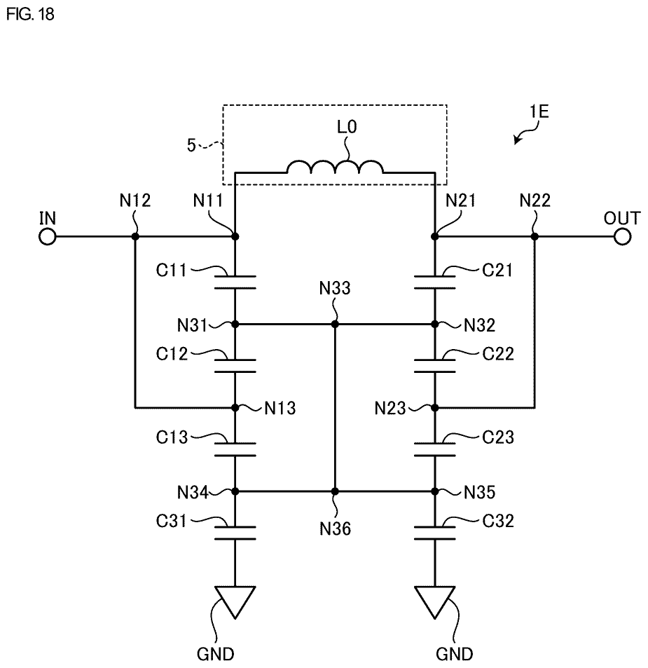

FIG. 18 is a circuit diagram showing the filter circuit according to the third embodiment. As shown in FIG. 18, the filter circuit 1E according to the third embodiment has first capacitors C11, C12, and C13 corresponding to the first capacitor C1 in the first embodiment, and second capacitors C21, C22, and C23 corresponding to the second capacitor C2 in the first embodiment. One electrode of the first capacitor C11 is connected to a node N11 on an input path connecting the input terminal IN and the inductor L0. The other electrode of the first capacitor C11 is connected to one electrode of the first capacitor C12. The other electrode of the first capacitor C12 is connected to one electrode of the first capacitor C13. The other electrode of the first capacitor C13 is connected to one electrode of the third capacitor C31. One electrode of the second capacitor C21 is connected to a node N21 on an input path connecting the output terminal OUT and the inductor L0. The other electrode of the second capacitor C21 is connected to one electrode of the second capacitor C22. The other electrode of the second capacitor C22 is connected to one electrode of the second capacitor C23. The other electrode of the second capacitor C23 is connected to one electrode of the third capacitor C31. The node N31 on the path connecting the first capacitor C11 and the first capacitor C12 and the node N32 on the path connecting the second capacitor C21 and the second capacitor C22 are electrically connected. A node N34 on the path connecting the first capacitor C13 and the third capacitor C31 and a node N35 on the path connecting the second capacitor C23 and the third capacitor C32 are electrically connected. A node N33 on the path connecting the node N31 and the node N32 and a node N36 on the path connecting the node N34 and the node N35 are electrically connected. The node N12 on the path connecting the input terminal IN and the node N11 and a node N13 on the path connecting the first capacitor C12 and the first capacitor C13 are electrically connected, and the node N22 on the path connecting the output terminal OUT and the node N21 and a node N23 on the path connecting the second capacitor C22 and the second capacitor C23 are electrically connected. Thus, the filter circuit 1E according to the second embodiment is equivalent to the circuit shown in FIG. 5. In the third embodiment, the first capacitor C1 shown in FIG. 5 corresponds to a capacitor having the combined capacitance of the first capacitors C11, C12, and C13, and the second capacitor C2 shown in FIG. 5 corresponds to a capacitor having the combined capacitance of the second capacitors C21, C22, and C23.

In the third embodiment, a portion of the third electrode 30D faces, on both sides in the Z direction, at least part of the portions of the first electrode 10D that overlap with each other. In the examples shown in FIGS. 13 to 17, the electrode pad 31 of the third electrode 30D faces, on both sides in the Z direction, the electrode pads 11 and 14 of the first electrode 10D. As a result, the first capacitor C11 is formed by the electrode pad 11 of the first electrode 10D and the electrode pad 31 of the third electrode 30D, and the first capacitor C12 is formed by the electrode pad 14 of the first electrode 10D and the electrode pad 36 of the third electrode 30D. That is, the electrode pad 11 of the first electrode 10D corresponds to one electrode of the first capacitor C11, the electrode pad 14 of the first electrode 10D corresponds to the other electrode of the first capacitor C12, and the electrode pad 31 of the third electrode 30D corresponds to the other electrode of the first capacitor C11 and one electrode of the first capacitor C12.

In the third embodiment, a portion of the third electrode 30D faces, on both sides in the Z direction, at least part of the portions of the second electrode 20D that overlap with each other. In the examples shown in FIGS. 13 to 17, the electrode pad 32 of the third electrode 30D faces, on both sides in the Z direction, the electrode pads 21 and 24 of the second electrode 20D. As a result, the second capacitor C21 is formed by the electrode pad 21 of the second electrode 20D and the electrode pad 32 of the third electrode 30D, and the second capacitor C22 is formed by the electrode pad 24 of the second electrode 20D and the electrode pad 37 of the third electrode 30D. That is, the electrode pad 21 of the second electrode 20D corresponds to one electrode of the second capacitor C21, the electrode pad 24 of the second electrode 20D corresponds to the other electrode of the second capacitor C22, and the electrode pad 32 of the third electrode 30D corresponds to the other electrode of the second capacitor C21 and one electrode of the second capacitor C22.

In the third embodiment, a portion of at least one of the first electrode 10D and the second electrode 20D faces, on both sides in the Z direction, at least part of the portions of the third electrode 30D that overlap with each other. In the examples shown in FIGS. 13 to 17, the electrode pad 14 of the first electrode 10D faces, on both sides in the Z direction, the electrode pads 31 and 36 of the third electrode 30D. The electrode pad 24 of the second electrode 20D faces, on both sides in the Z direction, the electrode pads 32 and 37 of the third electrode 30D. As a result, the first capacitor C13 is formed by the electrode pad 14 of the first electrode 10D and the electrode pad 36 of the third electrode 30D, and the second capacitor C23 is formed by the electrode pad 24 of the second electrode 20D and the electrode pad 37 of the third electrode 30D. That is, the electrode pad 14 of the first electrode 10D corresponds to one electrode of the first capacitor C13, the electrode pad 24 of the second electrode 20D corresponds to one electrode of the second capacitor C23, the electrode pad 36 of the third electrode 30D corresponds to the other electrode of the first capacitor C13, and the electrode pad 37 of the third electrode 30D corresponds to the other electrode of the second capacitor C23.

In the examples shown in FIGS. 13 to 17, the electrode pads 36 and 37 of the third electrode 30D face a portion of a fourth electrode 40D in the Z direction. As a result, the third capacitors C31 and C32 are formed by the electrode pads 36 and 37 of the third electrode 30D and a portion of the fourth electrode 40D. That is, the electrode pad 36 of the third electrode 30D corresponds to one electrode of the third capacitor C31, and the electrode pad 37 of the third electrode 30D corresponds to one electrode of the third capacitor C32.

As described above, in the filter circuit 1E according to the third embodiment, the first electrode 10 has portions (the electrode pads 11 and 14) that overlap with each other when viewed in the first direction. A portion of the third electrode 30 (the electrode pad 31) faces, on both sides in the first direction, at least part of the portions of the first electrode 10 that overlap with each other. With such a configuration, since the filter circuit 1E can be realized with a smaller space, a smaller filter circuit 1E can be provided.

Further, in the filter circuit 1E according to the third embodiment, the second electrode 20 has portions (the electrode pads 21 and 24) that overlap with each other when viewed in the first direction. A portion of the third electrode 30 (the electrode pad 32) faces, on both sides in the first direction, at least part of the portions of the second electrode 20 that overlap with each other. With such a configuration, since the filter circuit 1E can be realized with a smaller space, a smaller filter circuit 1E can be provided.

In the filter circuit 1E according to the third embodiment, the third electrode 30 has portions (the electrode pads 31, 32, 36, and 37) that overlap with each other when viewed in the first direction. A portion (the electrode pads 14 and 24) of at least one of the first electrode 10 and the second electrode 20 faces, on both sides in the first direction, at least part of the portions of the third electrode 30 that overlap with each other. With such a configuration, since the filter circuit 1E can be realized with a smaller space, a smaller filter circuit 1E can be provided.

### Fourth Modification

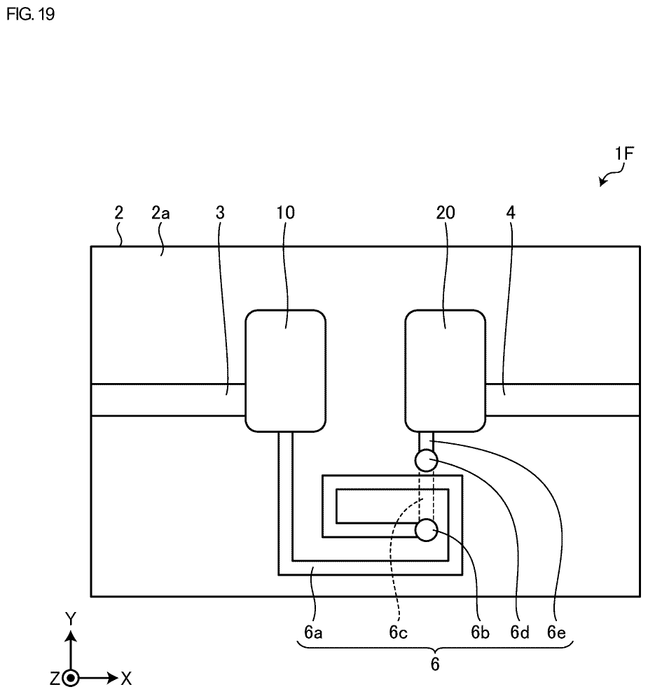

FIG. 19 is a schematic view showing a main surface of a substrate of a filter circuit according to a fourth modification. As shown in FIG. 19, in a filter circuit 1F according to the fourth modification, an element 6 including the inductor L0 is a conductor pattern formed on the main surface 2a of the substrate 2 and/or in the substrate 2. In the example of FIG. 19, the element 6 has lines 6a, 6c, and 6e and vias 6b and 6d. The line 6a extends in a spiral shape from the first electrode 10 and is provided on the main surface 2a of the substrate 2. The via 6b is connected to the line 6a and extends in the Z direction from the main surface 2a of the substrate 2 to the inside of the substrate 2. The line 6c is connected to the via 6b on the Y direction side of the second electrode 20 and extends in the Y direction toward the second electrode 20. Here, the line 6c extends so as to intersect the line 6a when viewed in plan in the Z direction. The via 6d is connected to the line 6c on the Y direction side of the second electrode 20 and extends in the Z direction from the inside of the substrate 2 to the main surface 2a of the substrate 2. The line 6e is connected to the via 6d and extends in the Y direction to the second electrode 20. Note that the shape of the element 6 described above is merely an example and is not limited to such an example, and the element 6 may be long enough to obtain sufficient inductance.

### Fifth Modification

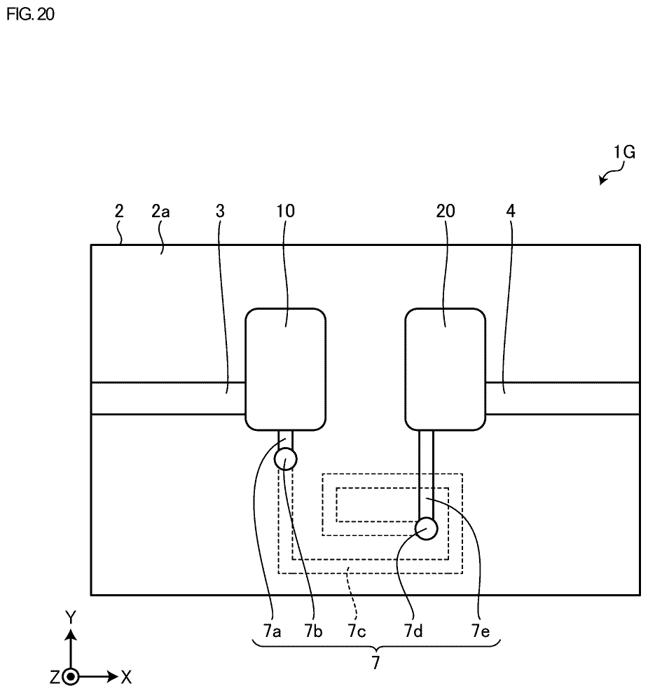

FIG. 20 is a schematic view showing a main surface of a substrate of a filter circuit according to a fifth modification. As shown in FIG. 20, in a filter circuit 1G according to the fifth modification, an element 7 including the inductor L0 is a conductor pattern formed on the main surface 2a of the substrate 2 and/or in the substrate 2. In the example of FIG. 20, the element 7 has lines 7a, 7c, and 7e and vias 7b and 7d. The line 7a extends in the Y direction from the first electrode 10 and is provided on the main surface 2a of the substrate 2. The via 7b is connected to the line 7a on the Y direction side of the first electrode 10 and extends in the Z direction from the main surface 2a of the substrate 2 to the inside of the substrate 2. The line 7c is connected to the via 7b and extends in a spiral shape. The via 7d is connected to the line 7c and extends in the Z direction from the inside of the substrate 2 to the main surface 2a of the substrate 2. The line 7e is connected to the via 7d and extends in the Y direction to the second electrode 20. Here, the line 7e extends so as to intersect the line 7a when viewed in plan in the Z direction. Note that the shape of the element 7 described above is merely an example and is not limited to such an example, and the element 7 may be long enough to obtain sufficient inductance.

In the filter circuits 1F and 1G according to the fourth modification and the fifth modification described above, the elements 6 and 7 are conductor patterns formed on the main surface 2a of the substrate 2 and/or in the substrate 2. With such a configuration, the filter circuits 1F and 1G can be provided on the inner layer of an LTCC substrate or the like, and can be laminated with other substrates as laminated components.

### Sixth Modification

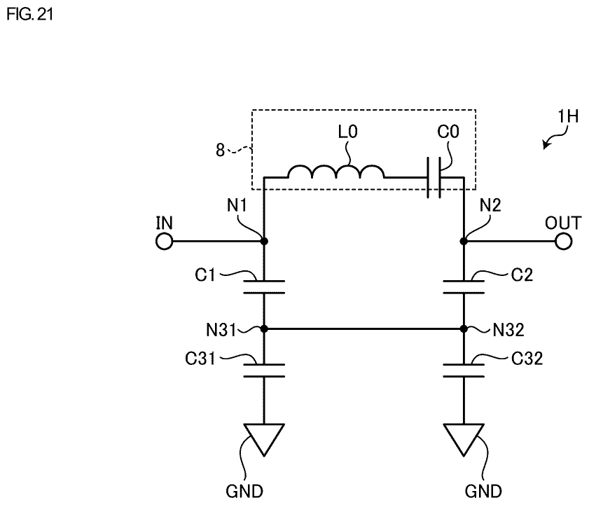

FIG. 21 is a schematic view showing the main surface of a substrate of a filter circuit according to a sixth modification. As shown in FIG. 21, in a filter circuit 1H according to the fifth modification, an element 8 including the inductor L0 further includes a capacitor C0 connected in series to the inductor L0. Even in such a case, the signal can be attenuated at a desired attenuation pole.

### Seventh Modification

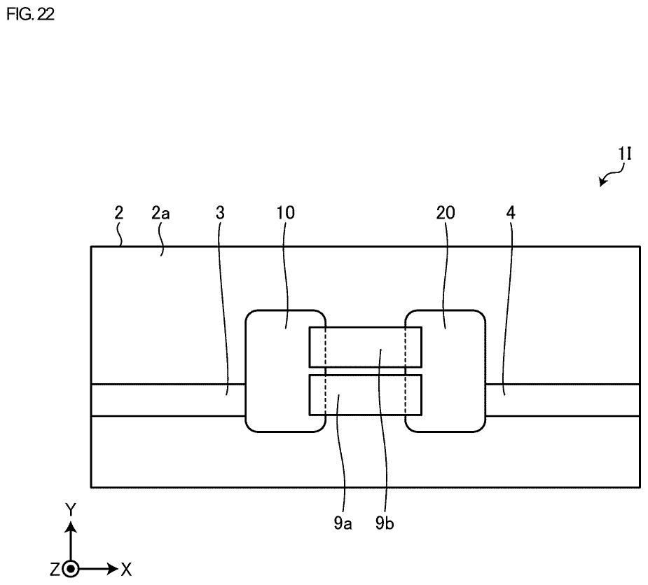

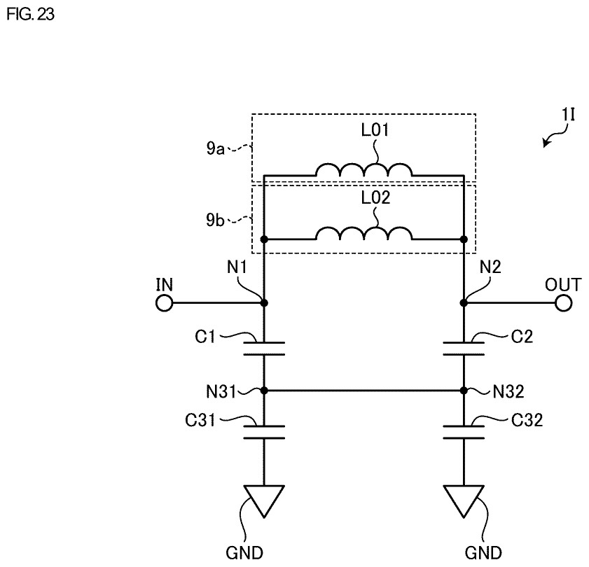

FIG. 22 is a circuit diagram of a filter circuit according to a seventh modification. FIG. 23 is a circuit diagram of the filter circuit according to the seventh modification. As shown in FIGS. 22 and 23, in a filter circuit 1I according to the fifth modification, a plurality of elements 9a and 9b are provided instead of the element 5 including the inductor L0. In the examples of FIGS. 22 and 23, the element 9a including an inductor L01 and the element 9b including an inductor L02 are provided. Even in such a case, the signal can be attenuated at a desired attenuation pole.

### Fourth Embodiment

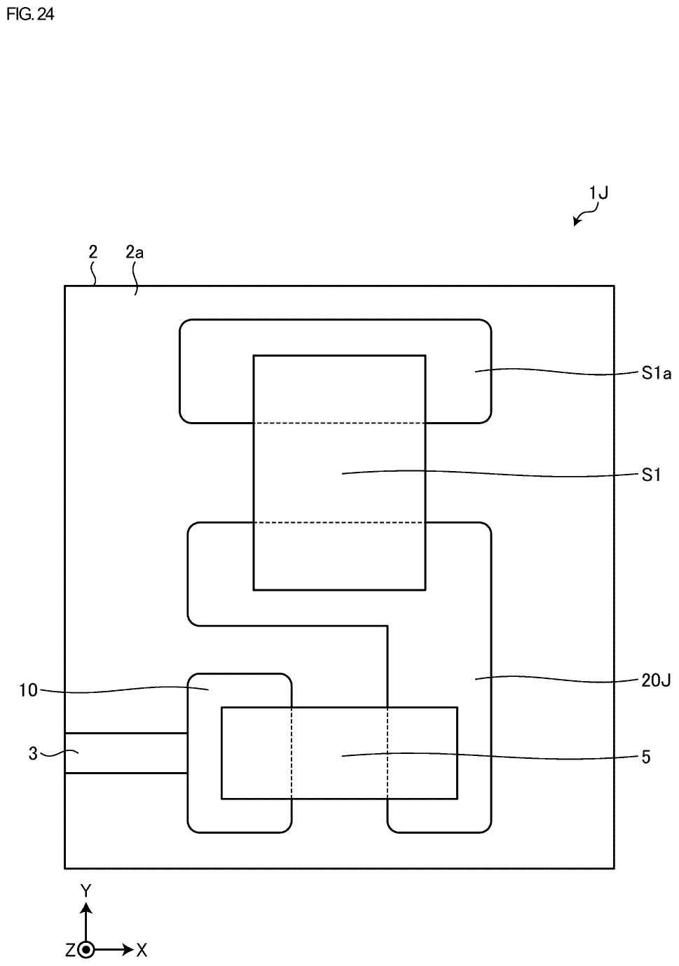

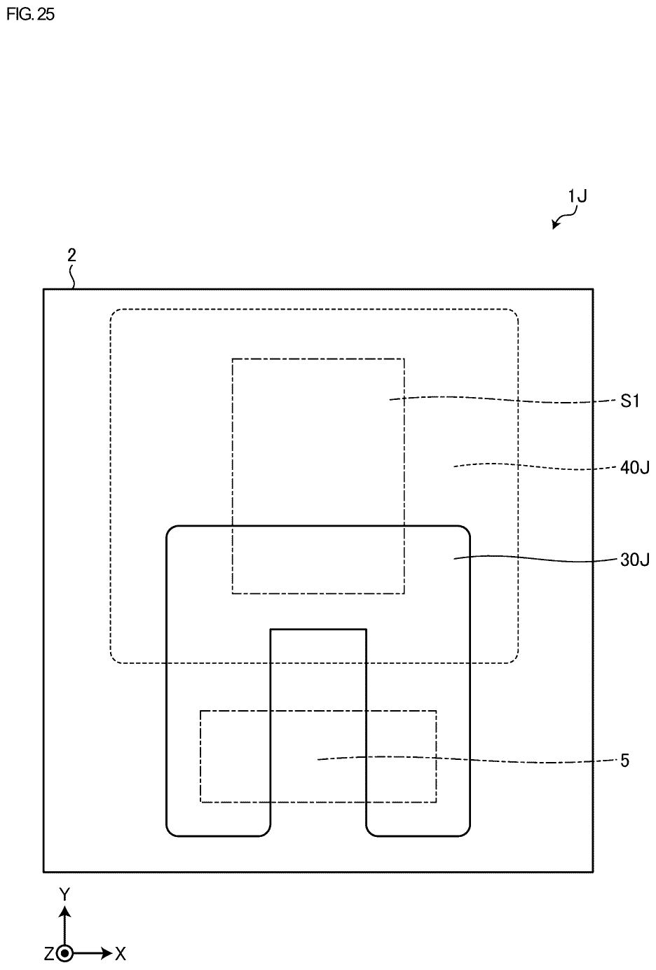

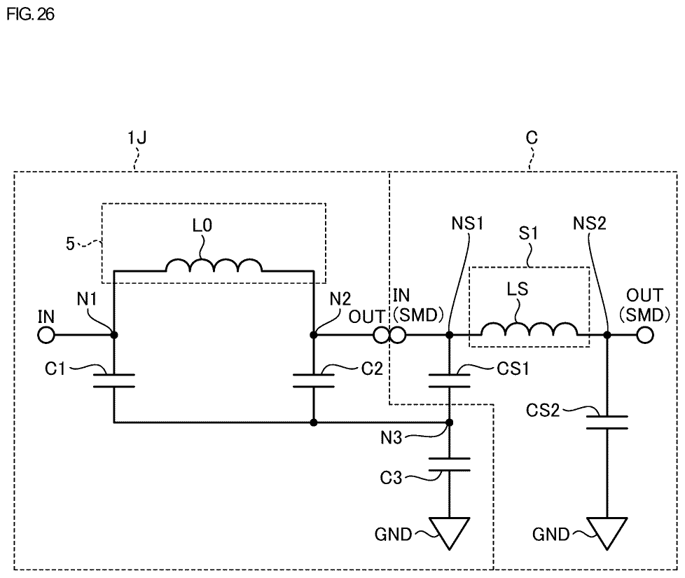

FIG. 24 is a schematic view showing a main surface of a substrate of a filter circuit according to a fourth embodiment. FIG. 25 is a schematic view showing the inside of the substrate of the filter circuit according to the fourth embodiment. FIG. 26 is a circuit diagram of the filter circuit according to the fourth embodiment. As shown in FIGS. 24 to 26, a filter circuit 1J according to the fourth embodiment differs from the first embodiment in that a second electrode 20J is connected to another element S1.

The element S1 is connected to the output terminal OUT of the filter circuit 1J according to the fourth embodiment. The element S1 is a surface mount device including, for example, an inductor LS, and is provided on the main surface 2a of the substrate 2. In the example shown in FIG. 24, the element S1 is provided in the Y direction of the element 5. One terminal of the element S1 is connected to the second electrode 20J, and the other terminal of the element S1 is connected to an electrode Sla on the main surface 2a. The electrode Sla is provided in the Y direction of the second electrode 20J, and is connected to another element (not shown). The sizes and shapes of the element S1 and the electrode Sla are only examples, and are not limited to the examples shown in FIG. 24.

In the fourth embodiment, the second electrode 20J is an electrode for mounting the other element S1. In the example shown in FIG. 24, the second electrode 20J is an L-shaped electrode, and the terminal of the element 5 on the output terminal OUT side is connected to a portion of the second electrode 20J extending in the Y direction, and one terminal of the other element S1 is connected to a portion of the second electrode 20J extending in the X direction.

In the example shown in FIG. 25, the shape of a third electrode 30J is U-shaped when viewed in plan in the Z direction. More specifically, when viewed in plan in the Z direction, the third electrode 30J is provided over a region overlapping with the first electrode 10 and a region overlapping with the first electrode 10, and the U-shape is obtained by removing a region overlapping with the element 5 from a rectangle.

In the example shown in FIG. 25, a fourth electrode 40 is provided on a portion of a main surface opposite to the main surface 2a of the substrate 2. In the example shown in FIG. 25, the fourth electrode 40 is a rectangular electrode provided in the Y direction with respect to the element 5. Further, when viewed in plan in the Z direction, the fourth electrode 40 does not overlap with the first electrode 10, but overlaps with only on a portion of the second electrode 20J extending in the X direction.

As shown in FIG. 26, the filter circuit 1J according to the fourth embodiment is connected at the output terminal OUT to a circuit C that has the element S1 including an inductor LS1. The circuit C includes an input terminal IN (SMD), an output terminal OUT (SMD), the inductor LS, and capacitors CS1 and CS2. The inductor LS is inserted in series into a signal path connecting the input terminal IN (SMD) and the output terminal OUT (SMD). The input terminal IN (SMD) is connected to the output terminal OUT of the filter circuit 1J. One electrode of the capacitor CS1 is connected to a node NS1 on a path connecting the input terminal IN (SMD) and the inductor L0. The other electrode of the capacitor CS1 is connected to the node N3. Here, the portion of the second electrode 20J extending in the Y direction corresponds to the output terminal OUT of the filter circuit 1J, and the portion of the second electrode 20J extending in the X direction corresponds to the input terminal IN (SMD) of the circuit C, which is to be described later. One electrode of the capacitor CS2 is connected to a node NS2 on a path connecting the output terminal OUT (SMD) and the inductor LS. The other electrode of the capacitor CS2 is connected to the reference potential (the ground GND). Here, the electrode Sla corresponds to the output terminal OUT (SMD) and the node NS2. Note that the configuration of the circuit C is only an example and is not limited to such an example.

In the example of FIG. 25, the portion of the third electrode 30J extending in the X direction faces a portion of the fourth electrode 40J. As a result, the third capacitor C3 is formed by the portion of the third electrode 30J extending in the X direction and the fourth electrode 40J. That is, the portion of the third electrode 30J extending in the X direction corresponds to one electrode of the third capacitor C3, and the portion of the fourth electrode 40 facing the third electrode 30J in the Z direction corresponds to the other electrode of the third capacitor C3.

In the example of FIG. 25, the portion of the second electrode 20J extending in the X direction faces the portion of the third electrode 30J extending in the X direction. As a result, the capacitor CS1 is formed by the portion of the second electrode 20J extending in the X direction and the portion of the third electrode 30J extending in the X direction. That is, the portion of the second electrode 20J extending in the X direction corresponds to one electrode of the capacitor CS1, and the portion of the third electrode 30J extending in the X direction corresponds to the other electrode of the capacitor CS1.

In the example of FIG. 25, the electrode Sla faces a portion of the fourth electrode 40J. As a result, the capacitor CS2 is formed by the electrode Sla and the portion of the fourth electrode 40J. That is, corresponds to one electrode of the capacitor CS2, and the portion of the fourth electrode 40J corresponds to the other electrode of the capacitor CS2.

In the fourth embodiment, the one to be connected to another element S1 is not limited to being the second electrode 20J, but can alternatively be the first electrode; it is sufficient if at least one of the first electrode and the second electrode is an electrode for mounting another element.

As described above, in the filter circuit 1J according to the fourth embodiment, at least one of the first electrode and the second electrode (the second electrode 20J) is an electrode for mounting another element S1. With such a configuration, since at least one of the first electrode and the second electrode (the second electrode 20J) serves both as an electrode plate of the first capacitor C1 or the second capacitor C2 and as a connection terminal of the element S1, a smaller module can be provided.

The embodiments described above are intended to facilitate understanding of the present disclosure, and are not intended to limit the interpretation thereof. The present disclosure may be changed/modified without departing from its scope, and the present disclosure also includes equivalents thereof.

For example, circuits other than the filter circuit 1 and the circuit C may be provided on the substrate 2.

For example, a protective film made of an insulator may be provided on the main surface 2a. The material of the protective film may be, for example, a dielectric used as a resist.

The present disclosure may have the following configurations as described above or in lieu of the above.

(1) A filter circuit comprising an input terminal; an output terminal; a signal path connecting the input terminal and the output terminal; an inductor inserted in series into the signal path; a first capacitor having one electrode connected to an input path connecting the input terminal and the inductor; a second capacitor having one electrode connected to an output path connecting the output terminal and the inductor; and a third capacitor having one electrode connected to the first capacitor and the second capacitor and the other electrode connected to a reference potential. The filter circuit including a substrate whose thickness is in a first direction; an element provided on a main surface of the substrate and/or in the substrate and including the inductor; a first electrode provided on the main surface of the substrate and/or in the substrate and connected to a terminal of the element on the input terminal side; a second electrode provided on the main surface of the substrate and/or in the substrate and connected to a terminal of the element on the output terminal side; a third electrode that is a floating electrode and that is provided in the substrate; and a fourth electrode provided on a main surface facing the main surface of the substrate in the first direction and/or in the substrate and connected to the reference potential. At least a portion of the first electrode and at least a portion of the third electrode face each other in the first direction. At least a portion of the second electrode and at least a portion of the third electrode face each other in the first direction. At least a portion of the third electrode and at least a portion of the fourth electrode face each other in the first direction. The portion of the first electrode facing the third electrode in the first direction is the electrode of the first capacitor. The portion of the second electrode facing the third electrode in the first direction is the electrode of the second capacitor. The portion of the third electrode facing the first electrode in the first direction is the other electrode of the first capacitor. The portion of the third electrode facing the second electrode in the first direction is the other electrode of the second capacitor. The portion of the third electrode facing the fourth electrode in the first direction is the electrode of the third capacitor, and the portion of the fourth electrode facing the third electrode in the first direction is the other electrode of the third capacitor.

(2) The filter circuit according to (1), wherein an electrostatic capacity of the first capacitor is 0.03 pF or larger, and an electrostatic capacity of the second capacitor is 0.03 pF or larger.

(3) The filter circuit according to (1) or (2), wherein the third electrode has a connecting portion that connects the portion facing at least a portion of the first electrode in the first direction and the portion facing at least a portion of the second electrode in the first direction.

(4) The filter circuit according to (3), wherein the connecting portion does not overlap with the element when viewed in plan in the first direction.

(5) The filter circuit according to any one of (1) to (4), further comprising a capacitor having one electrode connected to the input path and the other electrode connected to the reference potential, wherein at least a portion of the first electrode and at least a portion of the fourth electrode face each other in the first direction.

(6) The filter circuit according to any one of (1) to (5), further comprising a capacitor having one electrode connected to the output path and the other electrode connected to the reference potential. At least a portion of the second electrode and at least a portion of the fourth electrode face each other in the first direction.

(7) The filter circuit according to any one of (1) to (6), wherein the first electrode has portions that overlap with each other when viewed in the first direction, and a portion of the third electrode faces, on both sides in the first direction, at least part of the portions of the first electrode that overlap with each other.

(8) The filter circuit according to any one of (1) to (7), wherein the second electrode has portions that overlap with each other when viewed in the first direction, and a portion of the third electrode faces, on both sides in the first direction, at least part of the portions of the second electrode that overlap with each other.

(9) The filter circuit according to any one of (1) to (8), wherein the third electrode has portions that overlap with each other when viewed in the first direction, and a portion of at least one of the first electrode and the second electrode faces, on both sides in the first direction, at least part of the portions of the third electrode that overlap with each other.

(10) The filter circuit according to any one of (1) to (9), wherein the element is a surface mount device.

(11) The filter circuit according to any one of (1) to (9), wherein the element is a conductor pattern formed on the main surface of the substrate and/or in the substrate.

(12) The filter circuit according to any one of (1) to (11), wherein the element further includes a capacitor.

(13) The filter circuit according to any one of (1) to (12), wherein at least one of the first electrode and the second electrode is an electrode for mounting another element.

According to the present disclosure, a filter circuit capable of obtaining desired filter characteristics can be realized.

What is claimed is:

1. A filter circuit comprising:
an input terminal;
an output terminal;
a signal path connecting the input terminal and the output terminal;
an inductor inserted in series into the signal path;
a first capacitor having one electrode connected to an input path connecting the input terminal and the inductor;
a second capacitor having one electrode connected to an output path connecting the output terminal and the inductor; and
a third capacitor having one electrode connected to the first capacitor and the second capacitor and the other electrode connected to a reference potential,
the filter circuit including:
a substrate whose thickness is in a first direction;
an element that includes the inductor and is at least one of on a main surface of the substrate or in the substrate;
a first electrode that is connected to a terminal of the element on the input terminal side and is at least one of on the main surface of the substrate or in the substrate;
a second electrode that is connected to a terminal of the element on the output terminal side and is at least one of on the main surface of the substrate or in the substrate and;
a third electrode that is a floating electrode and that is in the substrate; and
a fourth electrode that is connected to the reference potential and is at least one of on a main surface facing the main surface of the substrate in the first direction or in the substrate,
wherein
at least a portion of the first electrode and at least a portion of the third electrode face each other in the first direction,
at least a portion of the second electrode and at least a portion of the third electrode face each other in the first direction,
at least a portion of the third electrode and at least a portion of the fourth electrode face each other in the first direction,
the portion of the first electrode facing the third electrode in the first direction is the electrode of the first capacitor,
the portion of the second electrode facing the third electrode in the first direction is the electrode of the second capacitor,
the portion of the third electrode facing the first electrode in the first direction is the other electrode of the first capacitor,
the portion of the third electrode facing the second electrode in the first direction is the other electrode of the second capacitor,
the portion of the third electrode facing the fourth electrode in the first direction is the electrode of the third capacitor, and
the portion of the fourth electrode facing the third electrode in the first direction is the other electrode of the third capacitor.

2. The filter circuit according to claim 1, wherein
an electrostatic capacity of the first capacitor is 0.03 pF or larger, and an electrostatic capacity of the second capacitor is 0.03 pF or larger.

3. The filter circuit according to claim 1, wherein
the third electrode has a connecting portion that connects the portion facing at least a portion of the first electrode in the first direction and the portion facing at least a portion of the second electrode in the first direction.

4. The filter circuit according to claim 3, wherein
the connecting portion does not overlap with the element when viewed in plan in the first direction.

5. The filter circuit according to claim 1, further comprising:
a capacitor having one electrode connected to the input path and the other electrode connected to the reference potential,
wherein
at least a portion of the first electrode and at least a portion of the fourth electrode face each other in the first direction.

6. The filter circuit according to claim 1, further comprising:
a capacitor having one electrode connected to the output path and the other electrode connected to the reference potential,
wherein
at least a portion of the second electrode and at least a portion of the fourth electrode face each other in the first direction.

7. The filter circuit according to claim 1, wherein
the first electrode has portions that overlap with each other when viewed in the first direction, and a portion of the third electrode faces, on both sides in the first direction, at least part of the portions of the first electrode that overlap with each other.

8. The filter circuit according to claim 1, wherein
the second electrode has portions that overlap with each other when viewed in the first direction, and a portion of the third electrode faces, on both sides in the first direction, at least part of the portions of the second electrode that overlap with each other.

9. The filter circuit according to claim 1, wherein
the third electrode has portions that overlap with each other when viewed in the first direction, and a portion of at least one of the first electrode and the second electrode faces, on both sides in the first direction, at least part of the portions of the third electrode that overlap with each other.

10. The filter circuit according to claim 1, wherein
the element is a surface mount device.

11. The filter circuit according to claim 1, wherein
the element is a conductor pattern that is at least one of on the main surface of the substrate or in the substrate.

12. The filter circuit according to claim 1, wherein
the element further includes a capacitor.

13. The filter circuit according to claim 1, wherein
at least one of the first electrode and the second electrode is an electrode for mounting another element.
